(19) United States
(12) Patent Application Publication
(10) Pub. No.: US 2025/0385659 A1
(43) Pub. Date: Dec. 18, 2025

(54) STEEP REJECTION AND SMALL SIZED MULTILAYER PIEZOELECTRIC SUBSTRATE DEVICE WITH PARTLY BURIED SURFACE ACOUSTIC WAVE DEVICE ELECTRODES

(71) Applicant: SKYWORKS SOLUTIONS, INC., Irvine, CA (US)

(72) Inventors: Rei Goto, Osaka-Shi (JP); Tatsuya Fujii, Nagaokakyo-Shi (JP)

(21) Appl. No.: 19/233,025

(22) Filed: Jun. 10, 2025

Related U.S. Application Data
(60) Provisional application No. 63/659,923, filed on Jun. 14, 2024.
(60) Provisional application No. 63/736,741, filed on Dec. 20, 2024.

(51) Int. Cl. H03H 9/25; H03H 3/08; H03H 9/02; H03H 9/145; H03H 9/64; H03H 9/72

(52) U.S. Cl. CPC H03H 9/25; H03H 3/08; H03H 9/02574; H03H 9/145; H03H 9/6483; H03H 9/725

(57) ABSTRACT

Aspects and embodiments disclosed herein include a die including a plurality of surface acoustic wave resonators comprising a substrate including at least one piezoelectric material layer, and at least one single-mode surface acoustic wave (SAW) resonator disposed on the substrate and including at least one electrode that is at least partially buried within the at least one piezoelectric material layer and that forms one of an interdigital transducer electrode or a reflector electrode of the single-mode SAW resonator. The die further includes at least one dual mode surface acoustic wave resonator disposed on the substrate and including interdigital transducer electrodes and reflector electrodes, none of the interdigital transducer electrodes and reflector electrodes of the at least one dual mode surface acoustic wave resonator being at least partially buried within the at least one piezoelectric material layer.

### CROSS-REFERENCE TO RELATED APPLICATIONS

This application claims priority under 35 U.S.C. § 119 (e) to U.S. Provisional Patent Application Ser. No. 63/736,741, titled “STEEP REJECTION AND SMALL SIZED MULTILAYER PIEZOELECTRIC SUBSTRATE DEVICE WITH PARTLY BURIED SURFACE ACOUSTIC WAVE DEVICE ELECTRODES,” filed Dec. 20, 2024 and to U.S. Provisional Patent Application Ser. No. 63/659,923, titled “STEEP REJECTION AND SMALL SIZED MULTILAYER PIEZOELECTRIC SUBSTRATE DEVICE WITH PARTLY BURIED SURFACE ACOUSTIC WAVE DEVICE ELECTRODES,” filed Jun. 14, 2024, the entire content of each being incorporated herein by reference for all purposes.

### BACKGROUND

### Field

Aspects and embodiments disclosed herein relate to multilayer piezoelectric substrate (MPS) surface acoustic wave (SAW) devices, and to radio frequency filters including same.

### Description of Related Technology

An acoustic wave device can include a plurality of resonators arranged to filter a radio frequency signal. Examples of acoustic wave resonators include surface acoustic wave (SAW) resonators. A surface acoustic wave resonator can include an interdigital transducer (IDT) electrode disposed on a piezoelectric substrate. The surface acoustic wave resonator can generate a surface acoustic wave on a surface of the piezoelectric layer on which the interdigital transducer electrode is disposed.

Acoustic wave filters can be implemented in radio frequency electronic systems. For instance, filters in a radio frequency front end of a mobile phone can include acoustic wave filters. An acoustic wave filter can be a band pass filter. A plurality of acoustic wave filters can be arranged as a multiplexer. For example, three acoustic wave filters can be arranged as a triplexer. As another example, four acoustic wave filters can be arranged as a quadplexer.

### SUMMARY

In accordance with one aspect, there is provided a die including a plurality of surface acoustic wave resonators. The die comprises a substrate including at least one piezoelectric material layer, at least one single-mode surface acoustic wave (SAW) resonator disposed on the substrate and including at least one electrode that is at least partially buried within the at least one piezoelectric material layer and that forms one of an interdigital transducer (IDT) electrode or a reflector electrode of the single-mode SAW resonator, and at least one dual mode surface acoustic wave (DMS) resonator disposed on the substrate and including interdigital transducer electrodes and reflector electrodes, none of the interdigital transducer electrodes and reflector electrodes of the at least one DMS resonator being at least partially buried within the at least one piezoelectric material layer.

In some embodiments, the substrate is a multilayer piezoelectric substrate.

In some embodiments, the electrode of the at least one single-mode SAW resonator is one of a multi-layer electrode including a layer of one of Mo, Pt, Ir, or W, or a single layer electrode including one of Mo, Pt, Ir, or W.

In some embodiments, the interdigital transducer electrodes and reflector electrodes of the at least one DMS resonator are one of multi-layer electrodes including a layer of one of Mo, Pt, Ir, or W, or single layer electrodes including one of Mo, Pt, Ir, or W.

In some embodiments, the substrate includes a plurality of piezoelectric material layers. In some embodiments, the at least one electrode of the at least one single-mode SAW resonator extends into each of the plurality of piezoelectric material layers.

In some embodiments, at least one electrode of the at least one single-mode SAW resonator is a multi-layer electrode including a lower electrode layer extending into at least one of the plurality of piezoelectric material layers and an upper electrode layer disposed above each of the plurality of piezoelectric material layers.

In some embodiments, the lower electrode layer extends into each of the plurality of piezoelectric material layers.

In some embodiments, the electrode of the at least one single-mode SAW resonator is an IDT electrode including bus bar electrodes and IDT electrode fingers each at least partially buried within the at least one piezoelectric material layer.

In some embodiments, the electrode of the at least one single-mode SAW resonator is an IDT electrode including IDT electrode fingers each at least partially buried within the at least one piezoelectric material layer and bus bar electrodes that are not at least partially buried within the substrate.

In some embodiments, the at least one electrode of the at least one single-mode SAW resonator is a reflector electrode.

In some embodiments, the at least one electrode of the at least one single-mode SAW resonator further includes an IDT electrode that is not at least partially buried within the substrate.

In some embodiments, the at least one single-mode SAW resonator includes a plurality of single-mode SAW resonators electrically connected and forming at least a portion of a radio frequency filter.

In some embodiments, the DMS resonator is electrically connected to the plurality of single-mode SAW resonators and is included in the radio frequency filter.

In some embodiments, the plurality of single-mode SAW resonators and the DMS resonator form a radio frequency duplexer.

In some embodiments, each of the resonators in a transmit side filter of the duplexer are at least partially buried within the at least one piezoelectric material layer and no resonators in a receive side filter of the duplexer are at least partially buried in the substrate.

In some embodiments, each of the resonators in a transmit side filter of the duplexer are at least partially buried within the at least one piezoelectric material layer, a first subset of resonators in a receive side filter of the duplexer closer to an antenna port of the duplexer than a second subset of resonators in the receive side filter of the duplexer is at least partially buried within the at least one piezoelectric material layer, and no resonators in the second subset of resonators are at least partially buried in the substrate.

In some embodiments, a first subset of the resonators in a transmit side filter of the duplexer further from an antenna port of the duplexer than a second subset of the resonators in the transmit side filter of the duplexer are at least partially buried within the at least one piezoelectric material layer, and no resonators in the second subset or in a receive side filter of the duplexer are at least partially buried in the substrate.

In some embodiments, the duplexer is included in a radio frequency device module.

In some embodiments, the radio frequency device module is included in a radio frequency device.

In accordance with another aspect, there is provided a method of forming a die including a plurality of surface acoustic wave resonators. The method comprises depositing a first layer of photoresist on an upper surface of a piezoelectric material layer of a substrate, developing the first layer of photoresist to form a first plurality apertures in the first layer of photoresist through which portions of the piezoelectric material layer are exposed, etching recesses within the exposed portions of the piezoelectric material layer, removing remaining portions of the first layer of photoresist from the upper surface of the piezoelectric material layer, depositing a first metal layer within the recesses, regions of the upper surface of the piezoelectric material layer other than the recesses being free of the first metal layer, depositing a second metal layer on the upper surface of the piezoelectric material layer and over the first metal layer within the recesses, depositing a second layer of photoresist on an upper surface of the second metal layer, developing the second layer of photoresist to form a second plurality apertures in the second layer of photoresist through which portions of the second metal layer are exposed, portions of the second layer of photoresist remaining disposed over the recesses, and etching the second metal layer through the second plurality of apertures to define first regions of the second metal layer disposed on the upper surface of the piezoelectric material layer both above and in contact with the first metal layer and second regions of the second metal layer disposed on the upper surface of the piezoelectric material layer and laterally displaced from the recesses.

In some embodiments, the first regions of the second metal layer and the first metal layer within the recesses are formed in a pattern defining partially buried interdigital transducer electrodes of a first surface acoustic wave resonator.

In some embodiments, the second regions of the second metal layer are formed in a pattern defining unburied interdigital transducer electrodes of a second acoustic wave resonator.

In some embodiments, the method further comprises removing first portions of the first metal layer from the upper surface of the piezoelectric material layer while leaving second portions of the first metal layer within the recesses.

### BRIEF DESCRIPTION OF THE DRAWINGS

FIG. 1A is a cross-sectional view of a portion of a SAW device having an IDT structure arranged on a piezoelectric layer;

FIG. 1B is an enlarged view of a portion of the IDT structure shown in FIG. 1A;

FIG. 1C is a plan view of a SAW device having the IDT structure illustrated in FIG. 1A;

FIG. 1D is a cross-sectional view of a SAW device including a temperature compensation layer on top of the IDT structure and substrate;

FIG. 2 is a schematic illustration of an example of a dual mode SAW resonator;

FIG. 3A is a cross-sectional view of a portion of a SAW device with a partially embedded IDT structure having two layers of Mo and Al or two layers of Cu and Al;

FIG. 3A′ is an enlarged view of the circled portion of the IDT structure shown in FIG. 3A;

FIG. 3B is a cross-sectional view of a portion of a SAW device with a partially embedded IDT structure having a layer of Cu, Pt, or Au where the IDT structure has a reverse tapered shape;

FIG. 3B′ is an enlarged view of the circled portion of the IDT structure shown in FIG. 3B;

FIG. 3C is a cross-sectional view of the structure of a section of a SAW device with a partially embedded IDT electrode structure in which the electrode fingers of the IDT electrode structure are multi-layered;

FIG. 4A is a cross-sectional view of a portion of a SAW device having multiple layers of piezoelectric material and single layer IDT electrode fingers disposed on top of the upper layer of piezoelectric material;

FIG. 4B is a cross-sectional view of a portion of a SAW device having multiple layers of piezoelectric material and IDT electrode fingers partially buried in the layers of piezoelectric material;

FIG. 4C is a cross-sectional view of a portion of a SAW device having multiple layers of piezoelectric material and single layer IDT electrode fingers with a reverse tapered shape partially buried in the layers of piezoelectric material;

FIG. 4D is a cross-sectional view of a portion of a SAW device having multiple layers of piezoelectric material and multi-layer IDT electrode fingers partially buried in the layers of piezoelectric material;

FIG. 4E is a cross-sectional view of a portion of a SAW device having multiple layers of piezoelectric material and multi-layer IDT electrode fingers disposed on top of the upper layer of piezoelectric material;

FIG. 4F is a cross-sectional view of a portion of a SAW device having multiple layers of piezoelectric material, multi-layer IDT electrode fingers disposed on top of the upper layer of piezoelectric material, and a trap rich layer disposed on a support substrate;

FIG. 4G is a cross-sectional view of a portion of a SAW device having multiple layers of piezoelectric material, multi-layer IDT electrode fingers partially buried in the layers of piezoelectric material, and a trap rich layer disposed on a support substrate;

FIG. 5A is a cross-sectional view of a portion of a SAW device having multiple layers of piezoelectric material, multi-layer IDT electrode fingers disposed on top of the upper layer of piezoelectric material, and a layer of piezoelectric material disposed on top of the IDT electrode fingers;

FIG. 5B is a cross-sectional view of a portion of a SAW device having multiple layers of piezoelectric material, multi-layer IDT electrode fingers partially buried within the multiple layers of piezoelectric material, and a layer of piezoelectric material disposed on top of the IDT electrode fingers;

FIG. 6 illustrates a die including multiple single-mode SAW resonators and a dual mode SAW (DMS) resonator;

FIG. 7 is a chart of an admittance curve of an example of a DMS resonator formed with partially buried IDT electrode fingers;

FIG. 8 illustrates different IDT electrode configurations for SAW resonators and a DMS resonator formed on the same die;

FIG. 9 illustrates one example of the IDT electrode structures of a DMS resonator and a single-mode SAW resonator formed on the same die;

FIG. 10 illustrates another example of the IDT electrode structures of a DMS resonator and a single-mode SAW resonator formed on the same die;

FIG. 11 illustrates another example of the IDT electrode structures of a DMS resonator and a single-mode SAW resonator formed on the same die;

FIG. 12A illustrates a SAW resonator having partially buried reflector electrodes and an unburied IDT electrode;

FIG. 12B illustrates a SAW resonator having unburied reflector electrodes and a partially buried IDT electrode;

FIG. 13A is a schematic of one example of a duplexer including SAW and DMS resonators as disclosed herein;

FIG. 13B is a schematic of another example of a duplexer including SAW and DMS resonators as disclosed herein;

FIG. 13C is a schematic of another example of a duplexer including SAW and DMS resonators as disclosed herein;

FIG. 13D is a schematic of another example of a duplexer including SAW and DMS resonators as disclosed herein;

FIG. 14A illustrates an act in a method of forming an example of partially buried IDT electrodes as disclosed herein;

FIG. 14B illustrates another act in a method of forming an example of partially buried IDT electrodes as disclosed herein;

FIG. 14C illustrates another act in a method of forming an example of partially buried IDT electrodes as disclosed herein;

FIG. 14D illustrates another act in a method of forming an example of partially buried IDT electrodes as disclosed herein;

FIG. 14E illustrates another act in a method of forming an example of partially buried IDT electrodes as disclosed herein;

FIG. 14F illustrates another act in a method of forming an example of partially buried IDT electrodes as disclosed herein;

FIG. 14G illustrates another act in a method of forming an example of partially buried IDT electrodes as disclosed herein;

FIG. 14H illustrates another act in a method of forming an example of partially buried IDT electrodes as disclosed herein;

FIG. 14I illustrates another act in a method of forming an example of partially buried IDT electrodes as disclosed herein;

FIG. 15 is a block diagram of one example of a filter module that can include one or more acoustic wave elements according to aspects of the present disclosure;

FIG. 16 is a block diagram of one example of a front-end module that can include one or more filter modules according to aspects of the present disclosure; and

FIG. 17 is a block diagram of one example of a wireless device including the front-end module of FIG. 16.

### DETAILED DESCRIPTION

The following description of certain embodiments presents various descriptions of specific embodiments. However, the innovations described herein can be embodied in a multitude of different ways, for example, as defined and covered by the claims. In this description, reference is made to the drawings where like reference numerals can indicate identical or functionally similar elements. It will be understood that elements illustrated in the figures are not necessarily drawn to scale. Moreover, it will be understood that certain embodiments can include more elements than illustrated in a drawing and/or a subset of the elements illustrated in a drawing. Further, some embodiments can incorporate any suitable combination of features from two or more drawings.

Acoustic wave filters can implement bandpass filters. For example, a bandpass filter can be formed from multilayer piezoelectric substrate surface acoustic wave (MPS SAW) resonators.

Parameters of acoustic wave filters desired by customers include small size, low change in performance, for example, passband frequency, with changes in temperature, often referred to as low temperature coefficient of frequency (TCF), high quality factor (Q), low insertion loss, and large bandwidth with steep passband edges to accommodate newer high bandwidth radio frequency communication bands.

To provide a solution for a SAW filter with a small overall size, MPS SAW filter packages with an embedded or partially buried interdigital transducer (IDT) structure may be utilized. Size reduction due to a low acoustic velocity, high electrode reflectivity, and large static capacitance between IDT electrode fingers of the SAW resonators included in such filters may be achieved by embedding the IDT in a high permittivity piezoelectric substrate.

While example SAW devices will now be discussed, the devices and methods disclosed herein can apply to other types of acoustic wave devices, including boundary wave devices and Lamb wave devices, for example.

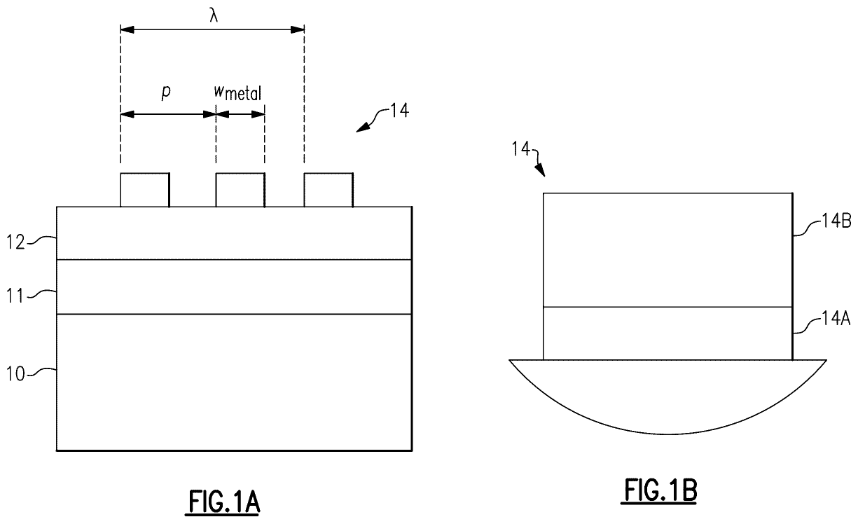

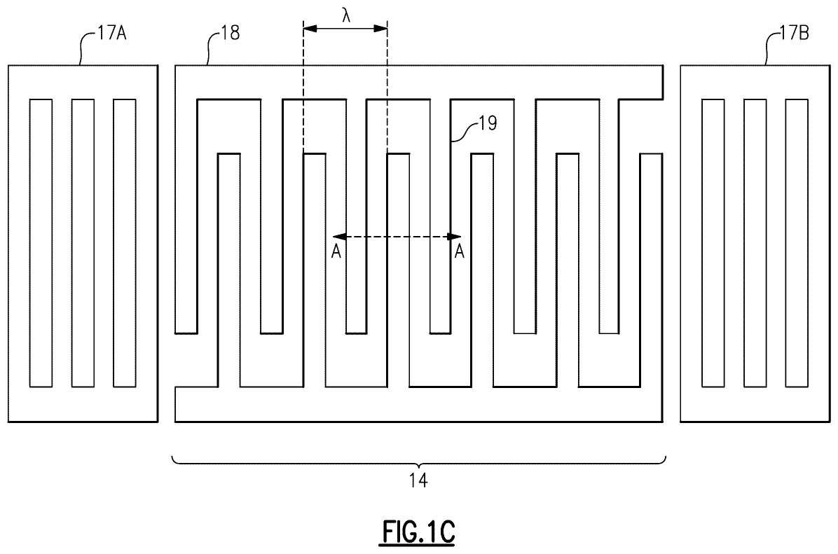

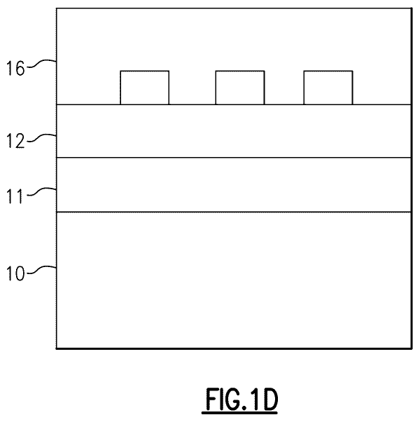

FIG. 1A is a cross sectional view of an interdigital transducer (IDT) structure 14 of a section of a SAW device arranged on a piezoelectric layer 12 of a multilayer piezoelectric substrate. The terms “SAW resonator” and “SAW device” are used synonymously herein unless the context indicates that a different form of device is being referenced. As illustrated, the SAW device includes a piezoelectric material layer 12 formed over a functional layer 11, which can be made of silicon dioxide (SiO₂), for example, and IDT electrodes 14. The SiO₂ layer may be formed on a support substrate 10. The support substrate 10 may be formed of, for example, silicon, aluminum nitride, sapphire, or another suitable material. In some embodiments, an MPS SAW device may comprise a temperature compensation (TC) layer 16 formed of, for example, SiO₂ over the IDT electrode 14 and piezoelectric material layer 12 as illustrated in FIG. 1D.

The piezoelectric material layer 12 can be a lithium-based piezoelectric material layer. For example, the piezoelectric material layer 12 can be a lithium niobate (LN) layer. As another example, the piezoelectric material layer 12 can be a lithium tantalate (LT) layer.

As illustrated, the IDT electrode 14 has a first side disposed on and in physical contact with the piezoelectric material layer 12 and a second side which may be in physical contact with the TC layer 16 (See FIG. 1D), when present. The IDT electrode 14 can include aluminum (Al), molybdenum (Mo), tungsten (W), gold (Au), silver (Ag), copper (Cu), platinum (Pt), iridium (Ir), ruthenium (Ru), titanium (Ti), the like, or any suitable combination or alloy thereof. The IDT electrode 14 can be a multi-layer IDT electrode in some embodiments. A ratio of the IDT width (wₘₑₜₐₗ) to the pitch (p) is usually defined as duty factor (DF) or metallization ratio (wₘₑₜₐₗ/p).

In an MPS SAW device as shown in FIG. 1D, the TC layer 16 and/or the functional layer 11 can have a positive TCF. This can at least partially compensate for a negative TCF of the piezoelectric material layer 12. As disclosed above, the piezoelectric material layer 12 can be lithium niobate or lithium tantalate, which both have a negative TCF. The TC layer 16 and/or the functional layer 11 can be a dielectric film. The TC layer 16 and/or the functional layer 11 can be a silicon dioxide (SiO₂) layer. In some other embodiments, a different TC layer and/or functional layer can be implemented. Some examples of other TC layers or functional layers include a tellurium dioxide (TeO₂) layer or a silicon oxyfluoride (SiOF) layer.

FIG. 1B is an enlarged view of an electrode finger of the IDT electrode 14 shown in FIG. 1A. In the example shown in FIG. 1B, the IDT electrode finger (and the IDT electrode as a whole) has two layers, for instance a layer 14A of molybdenum (Mo), and a layer 14B of aluminum (Al).

FIG. 1C is a plan view on a SAW device having an IDT electrode structure 14 as illustrated in FIG. 1A. In FIG. 1C, the view of the SAW devices shown in FIG. 1A or FIG. 1B is along the dashed line from A to A. The TC layer is not shown in FIG. 1C. The IDT electrode 14 is positioned between a first acoustic reflector 17A and a second acoustic reflector 17B. The acoustic reflectors 17A and 17B are separated from the IDT electrode 14 by respective gaps. The IDT electrode 14 includes a bus bar 18 and IDT electrode fingers 19 extending from the bus bar 18. The IDT electrode fingers 19 have a pitch of p=λ/2, where λ denotes the wavelength of the resonant frequency fs of the SAW device. The SAW device can include any suitable number of IDT electrode fingers 19.

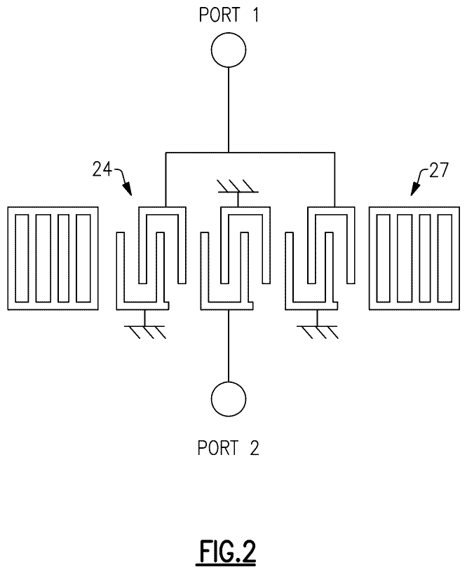

Another form of SAW device is a dual mode surface acoustic wave (DMS) resonator. A DMS resonator includes a plurality of IDT electrode structures disposed between acoustic reflectors. One example of a schematic for a three IDT DMS resonator is shown in FIG. 2. In the DMS resonator of FIG. 2 either Port 1 or Port 2 may be an input port and the other may be an output port. Three IDT electrode structures 24 are disposed between acoustic reflectors 27. The two outer IDT electrode structures 24 have a first bus bar electrically coupled to Port 1 and a second bus bar electrically connected to ground. The center IDT electrode structure 24 has a first bus bar electrically coupled to Port 2 and a second bus bar electrically connected to ground. Other configurations of DMS resonators are known to those in the art and the present disclosure is not to be limited to the particular configuration shown in FIG. 2. To distinguish between DMS resonators and MPS SAW resonators such as illustrated in plan view in FIG. 1C, MPS SAW resonators not configured as a DMS resonator may be referred to herein as “single-mode SAW” resonators.

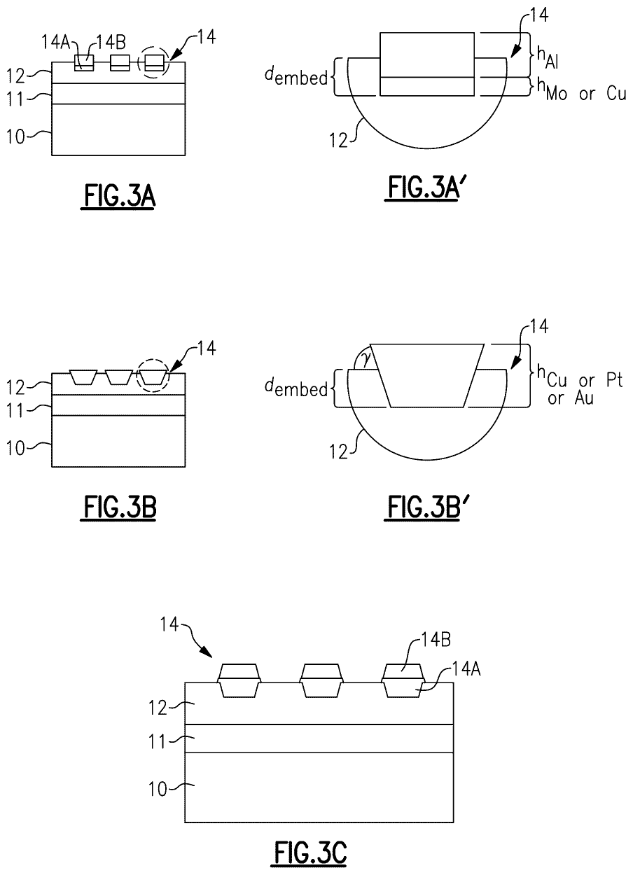

In some embodiments, SAW devices may include IDT electrode structures and/or acoustic reflectors with portions at least partially buried within the substrate. MPS SAW devices without partially buried electrodes are referred to herein as “Unburied MPS” devices while MPS SAW devices having partially buried electrodes are referred to herein as “Buried-MPS” devices. FIG. 3A is a cross-sectional view of an IDT electrode structure of a section of a SAW device with a partially embedded IDT electrode structure 14 having two layers 14A, 14B of Mo and Al, respectively, of Cu and Al, respectively, or of W and Al, respectively. The IDT electrode structure 14 may be multi-layered in some implementations. Mo, Cu, W, and Al are merely examples of the materials which may form the different layers of the IDT electrode structure 14.

The SAW device partly shown in FIG. 3A may comprise a support substrate 10, a layer of silicon dioxide (SiO₂) 11 formed on the support substrate 10, a piezoelectric material layer 12 formed on the layer of SiO₂, and the partially embedded IDT electrode structure 14.

FIG. 3A′ is an enlarged view of the circled portion of the IDT electrode 14 shown in FIG. 3A. As shown in FIG. 3A′, in an example including layers of Mo and Al, the layer of Mo has a height h_{Mo}, and the layer of Al has a height h_{Al}. The height h_{Mo} of the Mo layer may be in the range 0.02≤h_{Mo}/λ≤0.08, where λ corresponds to the geometry described in FIG. 1C. The wavelength 1 may be defined as the wavelength along an IDT propagation direction of a main mode. The main mode may be the mode that primarily contributes to forming the filter characteristics. The height h_{Al} of the Al layer may be in the range 0.04≤h_{Al}/λ≤0.08, where λ is defined as above.

In an example of an IDT structure including layers of Cu and Al, the layer of Cu has a height h_{Cu}. The height h_{Cu} of the Cu layer may be in the range 0.02≤h_{Cu}/λ≤0.08, where λ is defined as above. The height h_{Al} of the Al layer may be in the range 0.04≤h_{Al}/λ≤0.08, where λ is defined as above. Cu can be used instead of Mo. Cu plating is suitable for embedding the IDT electrode structure. Acoustic properties of Cu and Mo are similar.

The IDT electrode structure 14 has an embedment depth d_{embed}. The embedment depth d_{embed} in the piezoelectric layer 12 may be in the range 0.00≤d_{embed}/λ≤0.10, where λ is defined as above.

FIG. 3B is a cross-sectional view of an IDT electrode structure of a section of a SAW device with a partially embedded IDT electrode structure 14 having a layer of Cu, Pt, or Au where the IDT electrode structure 14 has a reverse tapered shape. The reverse tapered IDT electrode structure 14 may be multi-layered in some embodiments. Cu, Pt, or Au are merely examples of the material of which the IDT electrode structure 14 may be formed.

The SAW device partly shown in FIG. 3B may comprise a support substrate 10, a layer of silicon dioxide (SiO₂) 11 formed on the support substrate 10, a piezoelectric material layer 12 formed on the layer of SiO₂, and the partially embedded IDT electrode structure 14.

FIG. 3B′ is an enlarged view of the circled portion of the IDT electrode 14 shown in FIG. 3B. As shown in FIG. 3B′, the layer of Cu, Pt, or Au has a height h_{Cu or Pt or Au}. The height h_{Cu or Pt or Au} of the Cu, Pt, or Au layer may be in the range 0.06≤h_{Cu or Pt or Au}/λ≤0.16, where A corresponds to the geometry described in FIG. 1C.

The reverse tapered IDT electrode structure 14 has an embedment depth d_{embed}. The embedment depth d_{embed} in the piezoelectric layer 12 may be in the range 0.00<d_{embed}/λ≤0.16, where λ is defined as above. The reverse tapered IDT structure 14 may be fully embedded or formed in the piezoelectric material layer 12.

The reverse tapered IDT electrode structure 14 may have a reverse taper angle γ with respect to the surface of the piezoelectric material layer 12. The reverse taper angle γ may be in the range 65°≤γ≤90°, for example, 75°. Different sides of the reverse tapered IDT electrode structure 14 may have different reverse taper angles.

The reverse tapered IDT electrode structure 14 may be formed starting out from SiO₂ or amorphous Si deposition on the LT layer. The resulting substrate may be dry etched to form the shape of the reverse tapered IDT electrode structure. A seed layer may then be deposited, followed by electroplating and planarization. In the example of amorphous Si, XeF₂ gas may be used to remove the amorphous Si.

FIG. 3C is a cross-sectional view of the structure of a section of a SAW device with a partially embedded IDT electrode structure 14 similar to that of FIGS. 3B and 3B′ but where the electrode fingers of the IDT electrode structure 14 are multi-layered. A lower layer 14A of the electrode fingers of the IDT electrode structure 14 has a reverse tapered cross-sectional shape (like a trapezoid with the smaller parallel side on the bottom) and may be partially or wholly embedded in the piezoelectric material layer 12. The lower layer 14A of the electrode fingers may extend into the piezoelectric material layer 12 by, for example, about 10 nm. A flat non-tapered portion of the lower layer 14A of the electrode fingers may be disposed on top of the piezoelectric material layer 12 with the tapered portion centered below the non-tapered portion. An upper layer 14B of the electrode fingers of the IDT electrode structure 14 has a tapered cross-sectional shape (like a trapezoid with the longer parallel side on the bottom) and is disposed on top of the lower layer 14A.

The materials of the lower layer 14A and the upper layer 14B may be different and, in non-limiting examples, may include or consist of one or more of Al, Ti, Ni, Mo, W, Cu, Pt, or Ru. In some embodiments, the lower layer 14A is formed of a material with a higher density than the material of which the upper layer 14B is formed. In other embodiments, the reverse may be true—the lower layer 14A may be formed of a material with a lower density than the material of which the upper layer 14B is formed.

The taper angle of the sides of the upper layer 14B may be in the range of 65°-90°, for example, 75°. Different sides of the upper layer 14B may have different taper angles. The taper angle of the sides of the lower layer 14A and upper layer 14B may be the same as one another or different from one another.

While example SAW devices have been discussed with respect to FIGS. 3A-3C, aspects described with respect to the devices of FIGS. 3A-3C can apply to other types of acoustic wave devices, including boundary wave devices and Lamb wave devices. For example, boundary wave or Lamb wave devices can have layered structures in the similar or same arrangement of any of FIGS. 3A-3C and can have interdigital transducers partially or fully formed in the piezoelectric material layer.

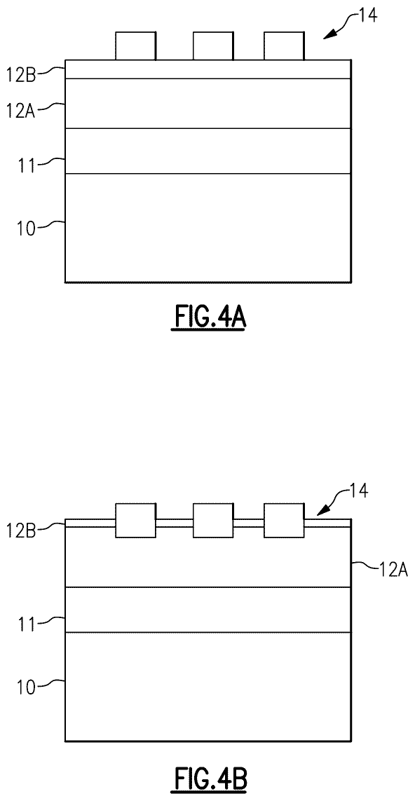

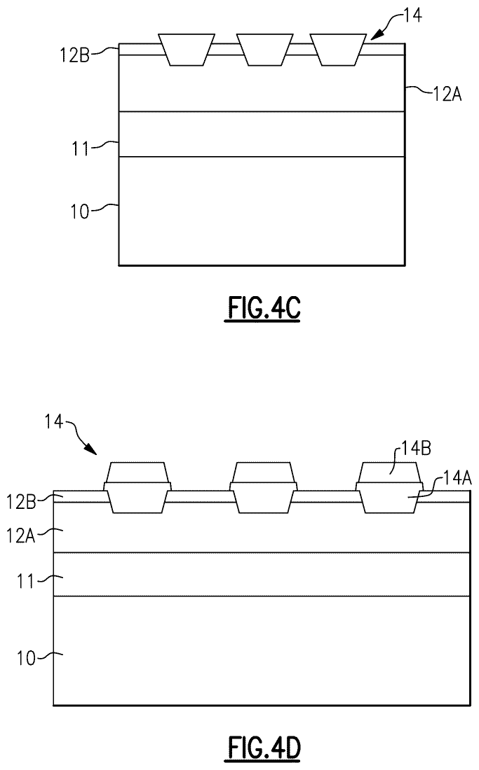

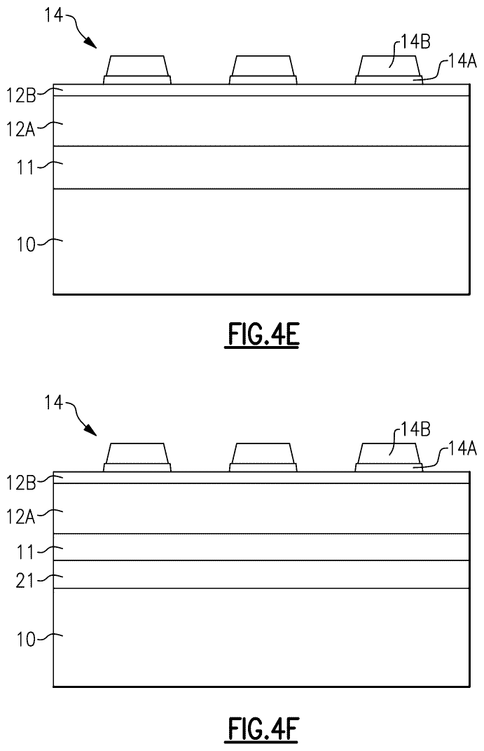

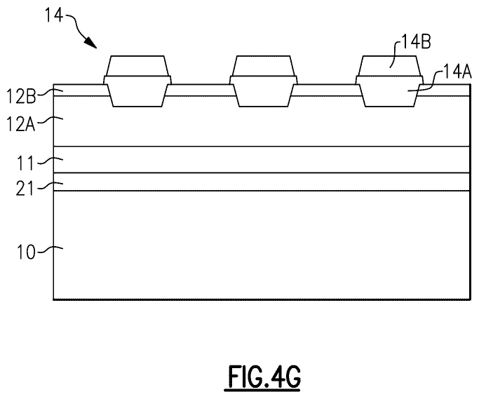

It has been discovered that the k² value of a SAW device as disclosed herein may be further increased by utilizing multiple layers of piezoelectric material. Instead of utilizing a single layer of piezoelectric material 12 as in the SAW device structures shown in FIGS. 1A and 3A-3C, the SAW device structures may include a first layer of piezoelectric material 12A and a second layer of piezoelectric material 12B deposited (for example, epitaxially deposited) on the first layer of piezoelectric material. As shown in FIGS. 4A-4D, this may be done for any of the SAW device structures shown in FIGS. 1A and 3A-3C or other SAW device structures disclosed herein. The first layer of piezoelectric material 12A and the second layer of piezoelectric material 12B may be formed of the same or of different lithium-based piezoelectric materials. In some embodiments, the first layer of piezoelectric material 12A (the lower layer of piezoelectric material) may be or may comprise lithium tantalate (LT, LiTaO₃) and the second layer of piezoelectric material 12B (the upper layer of piezoelectric material) may be or may comprise lithium niobate (LN, LiNbO₃). In other examples, one of the first or second layers of piezoelectric material may be or may comprise aluminum nitride.

In embodiments including single layer electrode fingers, the electrode fingers may be disposed entirely on top of the second layer of piezoelectric material 12B as shown in FIG. 4A or may be partially buried and extend downward into one or both of the layers of piezoelectric material 12A, 12B as shown in FIGS. 4B and 4C. In embodiments including electrode fingers with multiple metal layers 14A, 14B the entirety of the electrode fingers may be disposed entirely on top of the second layer of piezoelectric material 12B as shown in FIGS. 4E and 4F or one or both of the metal layers 14A, 14B may be partially buried and extend downward into one or both of the layers of piezoelectric material 12A, 12B as shown in FIG. 4D.

In some embodiments, the first layer of piezoelectric material 12A (the lower layer of piezoelectric material) may be thicker than the second layer of piezoelectric material 12B (the upper layer of piezoelectric material). In non-limiting embodiments, the first layer of piezoelectric material 12A may have a thickness of between 300 nm and 1,500 nm and the second layer of piezoelectric material 12B may have a thickness of between 10 nm and 300 nm. In embodiments in which the IDT electrode fingers extend downward into one or both of the layers of piezoelectric material 12A, 12B, the buried portions of the electrode fingers may extend about 10 nm into the one or both of the layers of piezoelectric material 12A, 12B.

In any of the embodiments disclosed herein in which the SAW device structure includes a SiO₂ layer 11 formed on a support substrate 10, a trap-rich layer 21, for example, a layer of poly-silicon may be disposed on top of the support substrate 10 between the support substrate 10 and the SiO₂ layer 11 as shown in the embodiment of FIG. 4F, in which the IDT electrode fingers are not buried in the piezoelectric material, or FIG. 4G, which is similar to the embodiment of FIG. 4D in which the IDT electrode fingers are partially buried in the piezoelectric material. The trap-rich layer may have a thickness of between 200 nm and 2000 nm or between 500 nm and 1500 nm.

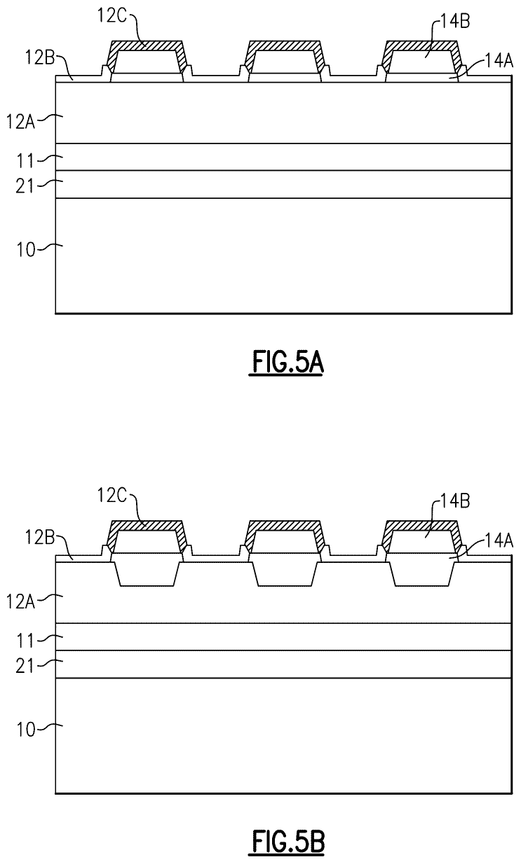

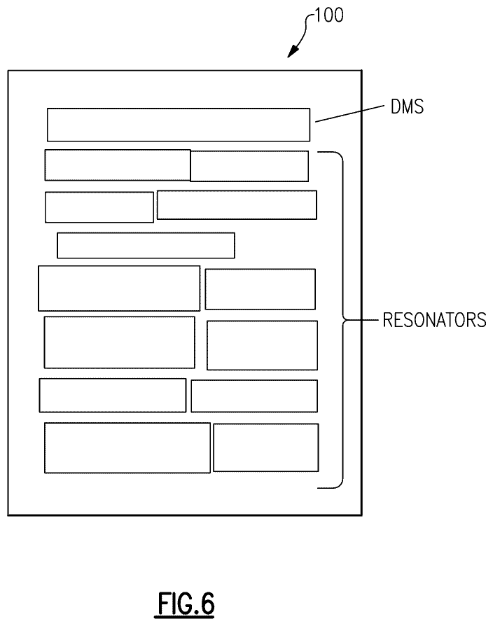

In further embodiments, a third layer of piezoelectric material 12C may be deposited on portions of the SAW device that are not covered by the second layer of piezoelectric material 12B, for example, on the IDT electrode fingers. The third layer of piezoelectric material 12C may be formed of the same material as the second layer of piezoelectric material 12B but may be deposited non-epitaxially, for example, by physical vapor deposition (e.g., sputtering), rather than by epitaxial deposition. FIG. 5A illustrates one embodiment that is similar to the embodiment of FIG. 4F, in which the IDT electrode fingers are disposed on the surface of the second layer of piezoelectric material 12B, with the addition of the third layer of piezoelectric material 12C. FIG. 5B illustrates one embodiment that is similar to the embodiment of FIG. 4G, in which the IDT electrode fingers are partially buried in the layers of piezoelectric material 12A, 12B, with the addition of the third layer of piezoelectric material 12C.

In some embodiments of SAW filter packages, multiple resonators may be formed on a single die. The resonators may include MPS SAW resonators having IDT electrode structures such as illustrated in the example of FIG. 1C (“single-mode SAW” resonators), DMS resonators having a configuration as illustrated in the example of FIG. 2, or a combination of these different resonator types. FIG. 6 illustrates an example of a die 100 having multiple single-mode SAW resonators, designated as simply “Resonators” in FIG. 6, as well as a DMS resonator, designated as “DMS” in FIG. 6. The single-mode SAW resonators and DMS resonator on the die 100 may in some embodiments together form a single filter or other form of acoustic wave device, for example, a duplexer.

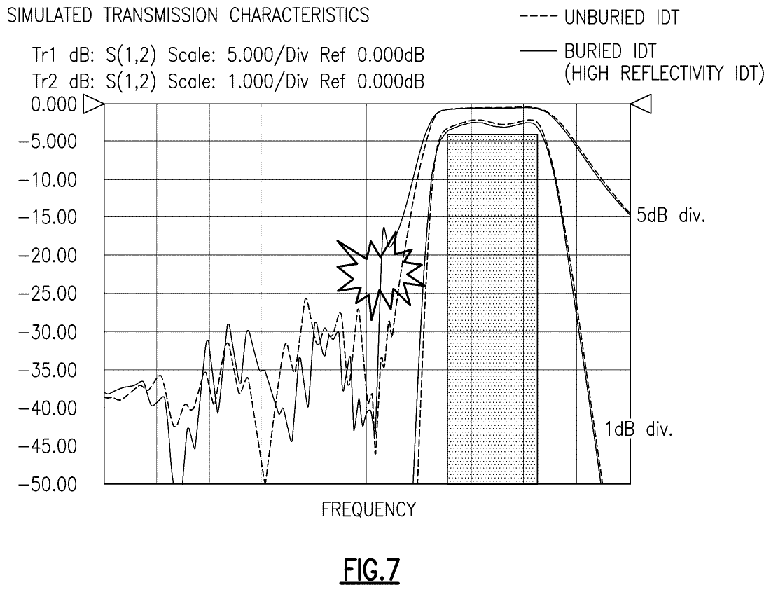

The higher reflectivity, decreased acoustic velocity, and increased capacitance resulting from at least partially burying the IDT and/or reflector electrodes in the piezoelectric material layer(s) of both single-mode SAW resonators and DMS resonators may provide for a reduction in size of both of these resonator types for a given operating frequency as opposed to designs utilizing electrodes not at least partially buried in the piezoelectric material layer(s) or substrate. The inventors have observed, however, that DMS resonators may have a sensitivity to the higher reflection exhibited by at least partially buried electrodes that may result in a discontinuity in the attenuation curve of the DMS resonators that makes it difficult to achieve steep attenuation skirts. An example of such a discontinuity is illustrated in the graph of FIG. 7, comparing the attenuation curves of a DMS resonator with unburied IDT electrodes (the “Unburied IDT” curve) against a DMS resonator having the same configuration but with partially buried IDT electrodes (the “Buried IDT” curve).

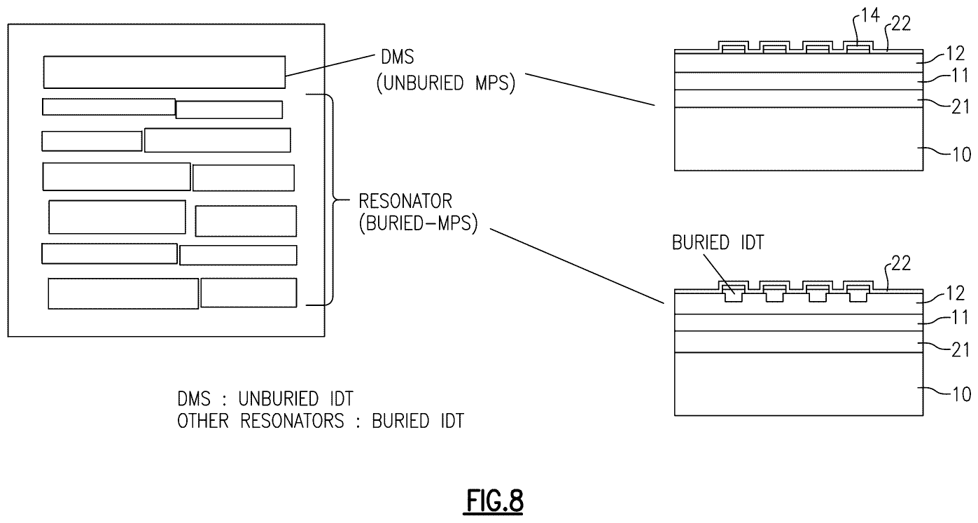

Accordingly, in SAW resonator die including both single-mode SAW and DMS resonators, one may obtain the size reduction benefits of utilizing at least partially IDT and/or reflector electrodes (Buried-MPS) in the single-mode SAW resonators, while using unburied electrodes (Unburied MPS) for the DMS resonator as illustrated in FIG. 8. In addition to the material layers previously discussed, the resonator structures shown in cross-section in FIG. 8 additionally include a protective layer 22 of, for example, SiN or SiON disposed on top of the IDT and reflector electrodes and piezoelectric material layer 12. Such a protective layer may be provided in any of the other resonator structures disclosed herein.

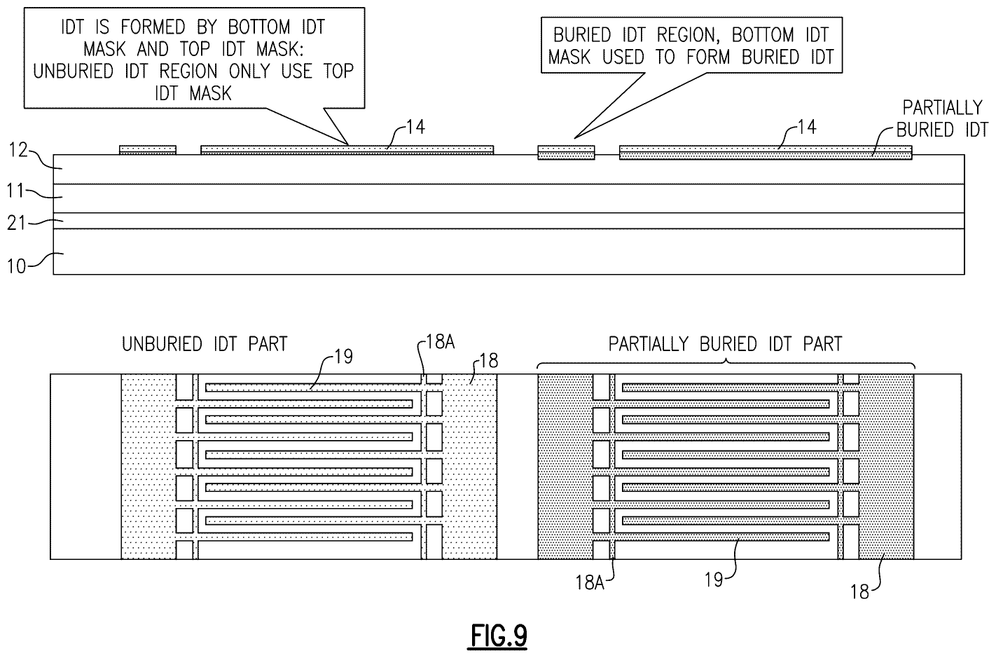

FIG. 9 illustrates one example of the IDT electrode structures of a DMS resonator and a single-mode SAW resonator formed on the same die including a single layer of piezoelectric material and with indicator numbers representing the same features as described above. The DMS resonator is formed with unburied IDT electrodes (the “Unburied IDT part”) while the single-mode SAW resonator is formed with partially buried IDT electrodes (the “Partially buried IDT part”). In the DMS resonator the bus bar electrodes 18 and IDT electrode fingers 19 are all unburied. In the single-mode resonator the bus bar electrodes 18 and IDT electrode fingers 19 are all partially buried in the substrate. In addition to the IDT electrode features described previously, either or both of the DMS resonator or the single-mode SAW resonator may further include mini bus bar electrodes 18A that are unburied in the DMS resonator and partially buried in the single-mode SAW resonator.

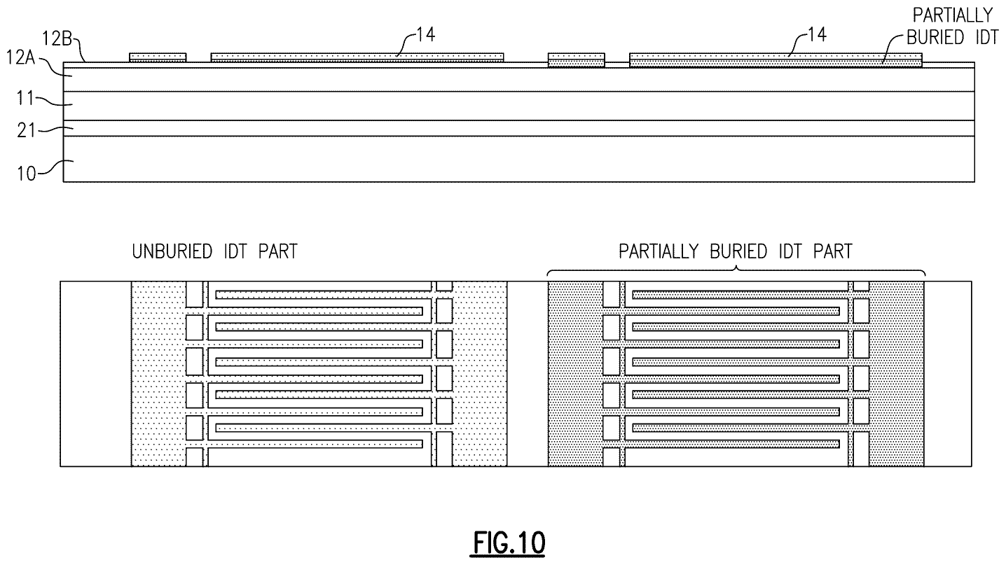

FIG. 10 illustrates another example of the IDT electrode structures of a DMS resonator and a single-mode SAW resonator formed on the same die including two layers of piezoelectric material and with indicator numbers representing the same features as described above. The DMS resonator is formed with unburied IDT electrodes (the “Unburied IDT part”) while the single-mode SAW resonator is formed with partially buried IDT electrodes (the “Partially buried IDT part”). In the DMS resonator the bus bar electrodes, mini bus bar electrodes, and IDT electrode fingers are all unburied. In the single-mode resonator the bus bar electrodes, mini bus bar electrodes, and IDT electrode fingers are all partially buried in the substrate.

FIG. 11 illustrates another example of the IDT electrode structures of a DMS resonator and a single-mode SAW resonator formed on the same die including a single layer of piezoelectric material and with indicator numbers representing the same features as described above. The DMS resonator is formed with unburied IDT electrodes (the “Unburied IDT part”) while the single-mode SAW resonator is formed with partially buried IDT electrodes (the “Partially buried IDT part”). In the DMS resonator the bus bar electrodes, mini bus bar electrodes, and IDT electrode fingers are all unburied. In the single-mode resonator the bus bar electrodes and mini bus bar electrodes are unburied, while the IDT electrode fingers in the aperture region in which IDT electrode fingers from one bus bar electrode are interleaved with IDT electrode fingers from the other bus bar electrode are partially buried in the substrate.

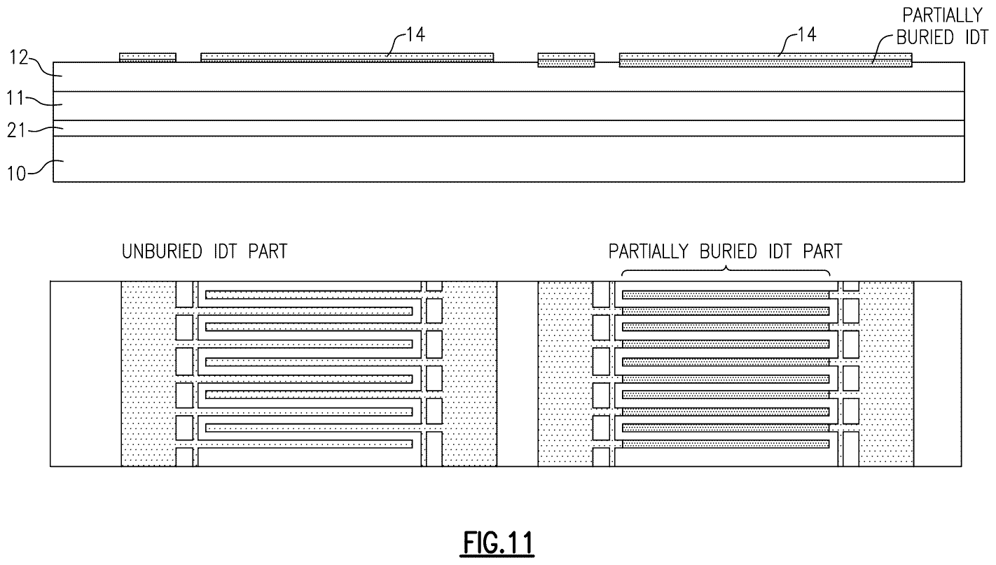

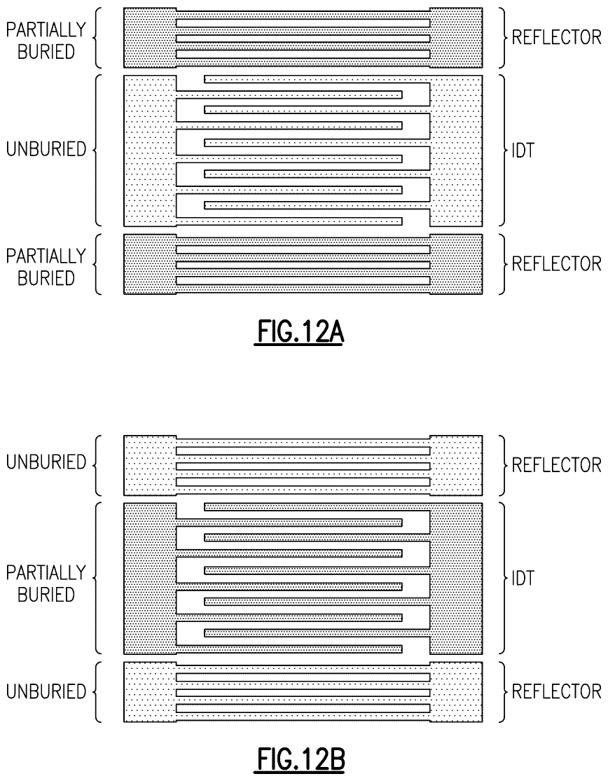

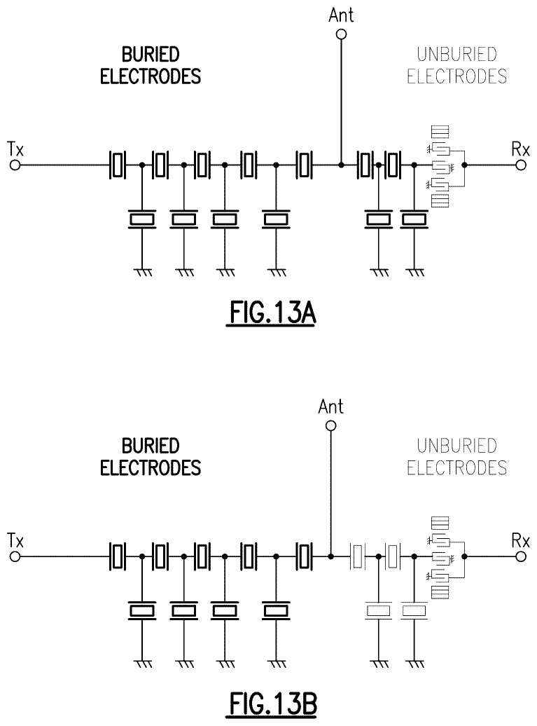

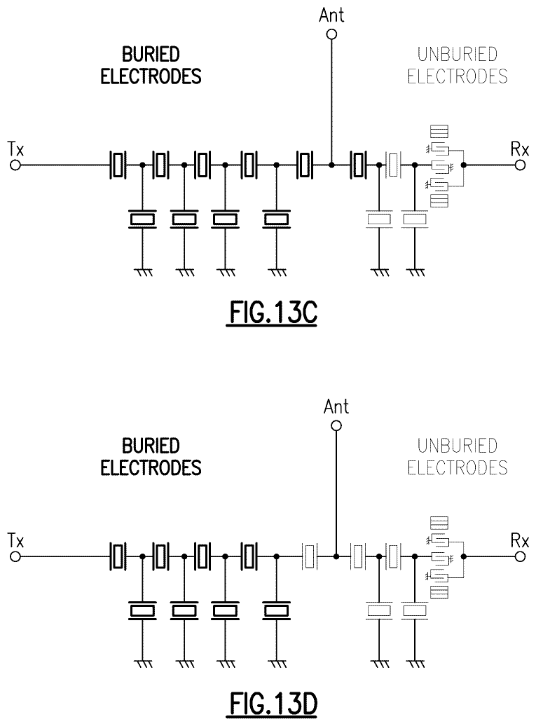

In further embodiments, for the single-mode SAW resonators, the reflector electrodes may be at least partially buried while the IDT electrodes are unburied (FIG. 12A) or the IDT electrodes may be at least partially buried while the reflector electrodes are unburied (FIG. 12B). In SAW filter structures such as duplexers the single-mode SAW resonators on the transmit side filter of the duplexer as well as the single-mode SAW resonators on the receive side filter of the duplexer may each include partially buried electrodes while a DMS resonator on the receive side filter may include only unburied electrodes as illustrated in FIG. 13A.

It has been observed that SAW resonators with at least partially buried electrodes may exhibit a greater power handling capability than SAW resonators with unburied electrodes. Accordingly, in SAW filter structures such as duplexers the SAW resonators (e.g., single-mode SAW resonators) in the transmit side filter of the duplexer may include partially buried electrodes while the SAW resonators (e.g., single-mode SAW resonators and a DMS resonator) in the receive side filter of the duplexer may include only unburied electrodes as illustrated in FIG. 13B. In another embodiment the SAW resonators in the transmit side filter of the duplexer as well as one or more SAW resonators closest to the antenna terminal in the receive side filter may include partially buried electrodes as illustrated in FIG. 13C. In a further embodiment, the SAW resonators in the receive side filter of the duplexer as well as one or more SAW resonators closest to the antenna terminal in the transmit side filter may include partially unburied electrodes while the remainder of the SAW resonators in the transmit side filter include partially buried electrodes as illustrated in FIG. 13D.

As disclosed above, multiple SAW resonators as disclosed herein may be combined into a filter, for example, an RF ladder filter such as that used as the transmit side filter of the duplexers of FIGS. 13A-13D and that includes a plurality of series resonators (five series resonators in the transmit side filters of FIGS. 13A-13D), and a plurality of parallel (or shunt) resonators (four shunt resonators in the transmit side filters of FIGS. 13A-13D). As shown, the plurality of series resonators are connected in series between the input (the Tx terminal) and the output of the RF ladder filter (the antenna), and the plurality of parallel resonators are respectively connected between series resonators and ground in a shunt configuration. Other filter structures and other circuit structures known in the art that may include SAW devices or resonators, for example, duplexers, baluns, etc., may also be formed including examples of SAW resonators as disclosed herein.

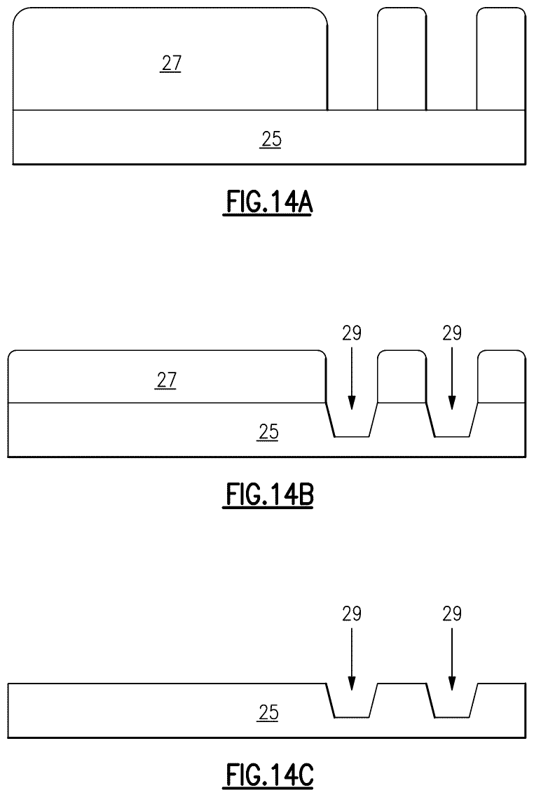

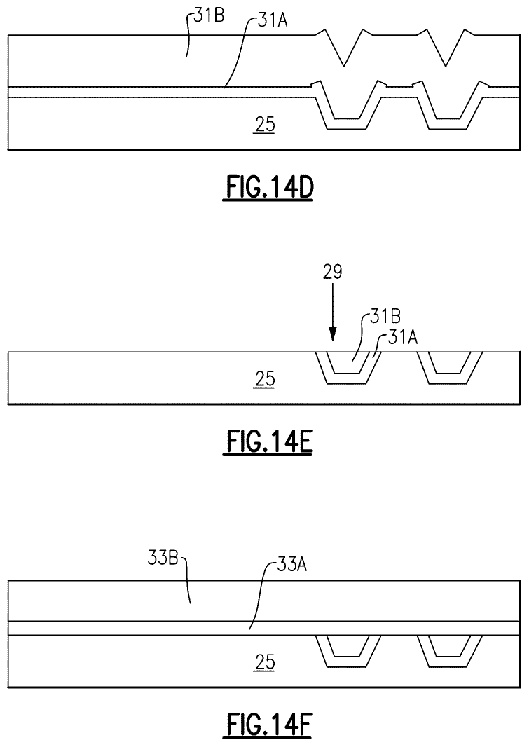

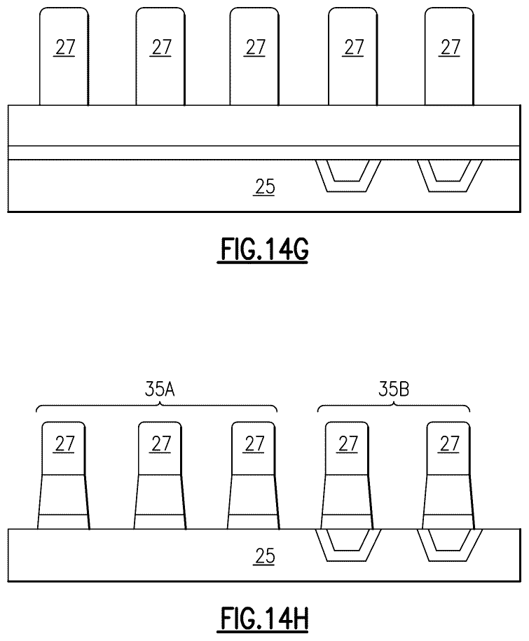

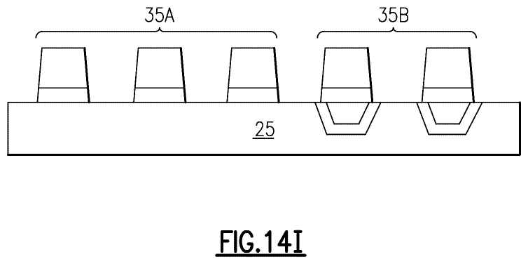

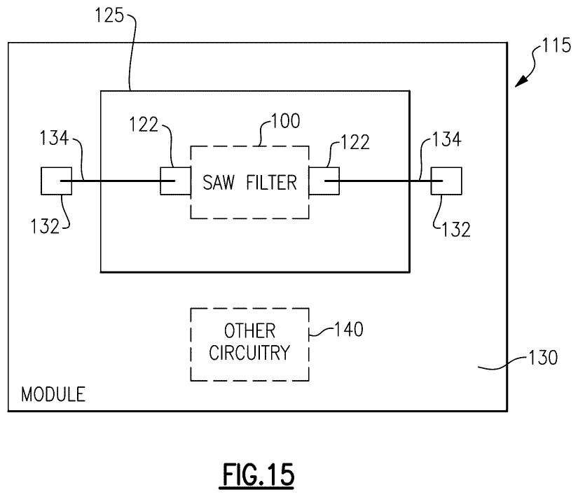

An example of a method of forming a partially buried IDT electrode for a SAW resonator as disclosed herein is illustrated in FIGS. 14A-14I. FIG. 14A illustrates a piezoelectric material substrate 25 that has been coated with photoresist 27 that has been patterned to define exposed regions of the substrate 25 in which partially buried IDT electrodes are to be formed. The piezoelectric material substrate 25 is illustrated as a single layer substrate for the sake of clarity, but it is to be understood that the piezoelectric material substrate 25 may be a multilayer piezoelectric substrate and/or may include a trap-rich layer or any of the layers of material in the examples of substrates described above. The structure illustrated in FIG. 14A is etched, for example, via anisotropic plasma etching or isotropic wet etching to form recesses 29 in the substrate 25 in which portions of the buried IDT electrodes will be formed. The photoresist 27 is then stripped to expose the full upper surface of the substrate 25 as illustrated in FIG. 14C. Metal that will form the buried portions of the partially buried IDT electrode is then deposited on the upper surface of the substrate 25 and within the recesses 29, for example, by sputtering. This metal may include an optional lower adhesion layer 31A formed of, for example, Ti, Cr, or an alloy thereof, and buried electrode material layer 31B formed of, for example, W, Mo, Pt, Ru, or another suitable metal as illustrated in FIG. 14D. The structure is then planarized in a chemical-mechanical polishing (CMP) operation to remove the metal layers 31A, 31B from the upper surface of the substrate while leaving these metal layers within the recesses 29 as shown in FIG. 14E. Additional IDT electrode metal layers 33A, 33B are then deposited on the upper surface of the substrate 25 and over the metal layers 31A, 31B by, for example, sputtering as illustrated in FIG. 14F. Metal layer 33A may be, for example, W, Mo, Pt, Ru, Ti or another suitable metal and metal layer 33B may be, for example, Al, Cu, or an alloy thereof. The combination of layers 33A and 31B may form the lower electrode layer 14A referenced above and metal layer 33B may form the upper electrode layer 14B referenced above. Another layer of photoresist 27 is then deposited on the metal layer 33B and patterned to define regions beneath the portions of the photoresist 27 that is not removed where unburied IDT electrodes and unburied portions of the partially buried IDT electrodes will be formed as illustrated in FIG. 14G. Regions of the metal layers 33A, 33B that are exposed by the patterned photoresist 27 are then etched to define the unburied IDT electrodes 35A and unburied portions of the partially buried IDT electrodes 35B as illustrated in FIG. 14H. The photoresist 27 is then stripped to leave behind the unburied IDT electrodes 35A and the partially buried IDT electrodes 35B on and partially within the substrate 25, respectively, as illustrated in FIG. 14I.

Examples of the SAW devices, e.g., SAW resonators discussed herein can be implemented in a variety of packaged modules. Some example packaged modules will now be discussed in which any suitable principles and advantages of the SAW devices discussed herein can be implemented. FIGS. 15, 16, and 17 are schematic block diagrams of illustrative packaged modules and devices according to certain embodiments.

As discussed above, surface acoustic wave resonators can be used in surface acoustic wave (SAW) RF filters. In turn, a SAW RF filter using one or more surface acoustic wave elements may be incorporated into and packaged as a module that may ultimately be used in an electronic device, such as a wireless communications device, for example. FIG. 15 is a block diagram illustrating one example of a module 115 including a SAW filter 100. The SAW filter 100 may be implemented on one or more die(s) 125 including one or more connection pads 122. For example, the SAW filter 100 may include a connection pad 122 that corresponds to an input contact for the SAW filter and another connection pad 122 that corresponds to an output contact for the SAW filter. The packaged module 115 includes a packaging substrate 130 that is configured to receive a plurality of components, including the die 125. A plurality of connection pads 132 can be disposed on the packaging substrate 130, and the various connection pads 122 of the SAW filter die 125 can be connected to the connection pads 132 on the packaging substrate 130 via electrical connectors 134, which can be solder bumps or wirebonds, for example, to allow for passing of various signals to and from the SAW filter 100. The module 115 may optionally further include other circuitry die 140, for example, one or more additional filter(s), amplifiers, pre-filters, modulators, demodulators, down converters, and the like, as would be known to one of skill in the art of semiconductor fabrication in view of the disclosure herein. In some embodiments, the module 115 can also include one or more packaging structures to, for example, provide protection and facilitate easier handling of the module 115. Such a packaging structure can include an overmold formed over the packaging substrate 130 and dimensioned to substantially encapsulate the various circuits and components thereon.

Various examples and embodiments of the SAW filter 100 can be used in a wide variety of electronic devices. For example, the SAW filter 100 can be used in an antenna duplexer, which itself can be incorporated into a variety of electronic devices, such as RF front-end modules and communication devices.

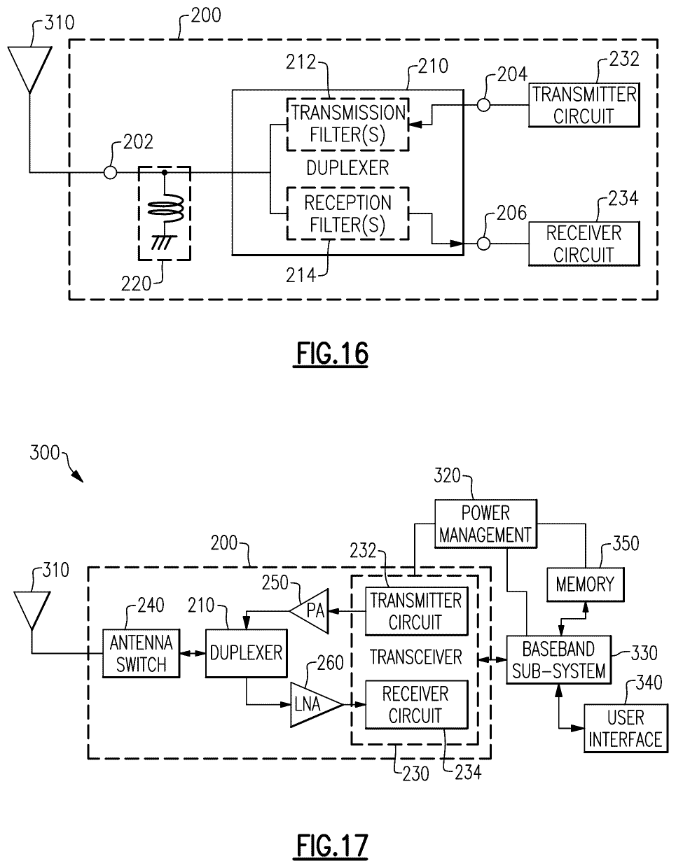

Referring to FIG. 16, there is illustrated a block diagram of one example of a front-end module 200, which may be used in an electronic device such as a wireless communications device (e.g., a mobile phone) for example. The front-end module 200 includes an antenna duplexer 210 having a common node 202, an input node 204, and an output node 206. An antenna 510 is connected to the common node 202.

The antenna duplexer 210 may include one or more transmission filters 212 connected between the input node 204 and the common node 202, and one or more reception filters 214 connected between the common node 202 and the output node 206. The passband(s) of the transmission filter(s) are different from the passband(s) of the reception filters. Examples of the SAW filter 100 can be used to form the transmission filter(s) 212 and/or the reception filter(s) 214. An inductor or other matching component 220 may be connected at the common node 202.

The front-end module 200 further includes a transmitter circuit 232 connected to the input node 204 of the duplexer 210 and a receiver circuit 234 connected to the output node 206 of the duplexer 210. The transmitter circuit 232 can generate signals for transmission via the antenna 310, and the receiver circuit 234 can receive and process signals received via the antenna 310. In some embodiments, the receiver and transmitter circuits are implemented as separate components, as shown in FIG. 16, however, in other embodiments these components may be integrated into a common transceiver circuit or module. As will be appreciated by those skilled in the art, the front-end module 200 may include other components that are not illustrated in FIG. 16 including, but not limited to, switches, electromagnetic couplers, amplifiers, processors, and the like.

FIG. 17 is a block diagram of one example of a wireless device 300 including the antenna duplexer 210 shown in FIG. 16. The wireless device 300 can be a cellular phone, smart phone, tablet, modem, communication network or any other portable or non-portable device configured for voice or data communication. The wireless device 300 can receive and transmit signals from the antenna 310. The wireless device includes an embodiment of a front-end module 200 similar to that discussed above with reference to FIG. 16. The front-end module 200 includes the duplexer 210, as discussed above. In the example shown in FIG. 17 the front-end module 200 further includes an antenna switch 240, which can be configured to switch between different frequency bands or modes, such as transmit and receive modes, for example. In the example illustrated in FIG. 17, the antenna switch 240 is positioned between the duplexer 210 and the antenna 310; however, in other examples the duplexer 210 can be positioned between the antenna switch 240 and the antenna 310. In other examples the antenna switch 240 and the duplexer 210 can be integrated into a single component.

The front-end module 200 includes a transceiver 230 that is configured to generate signals for transmission or to process received signals. The transceiver 230 can include the transmitter circuit 232, which can be connected to the input node 204 of the duplexer 210, and the receiver circuit 234, which can be connected to the output node 206 of the duplexer 210, as shown in the example of FIG. 17.

Signals generated for transmission by the transmitter circuit 232 are received by a power amplifier (PA) module 250, which amplifies the generated signals from the transceiver 230. The power amplifier module 250 can include one or more power amplifiers. The power amplifier module 250 can be used to amplify a wide variety of RF or other frequency-band transmission signals. For example, the power amplifier module 250 can receive an enable signal that can be used to pulse the output of the power amplifier to aid in transmitting a wireless local area network (WLAN) signal or any other suitable pulsed signal. The power amplifier module 250 can be configured to amplify any of a variety of types of signal, including, for example, a Global System for Mobile (GSM) signal, a code division multiple access (CDMA) signal, a W-CDMA signal, a Long-Term Evolution (LTE) signal, or an EDGE signal. In certain embodiments, the power amplifier module 250 and associated components including switches and the like can be fabricated on gallium arsenide (GaAs) substrates using, for example, high-electron mobility transistors (pHEMT) or insulated-gate bipolar transistors (BiFET), or on a Silicon substrate using complementary metal-oxide semiconductor (CMOS) field effect transistors.

Still referring to FIG. 17, the front-end module 200 may further include a low noise amplifier module 260, which amplifies received signals from the antenna 310 and provides the amplified signals to the receiver circuit 234 of the transceiver 230.

The wireless device 300 of FIG. 17 further includes a power management sub-system 320 that is connected to the transceiver 230 and manages the power for the operation of the wireless device 300. The power management system 320 can also control the operation of a baseband sub-system 330 and various other components of the wireless device 300. The power management system 320 can include, or can be connected to, a battery (not shown) that supplies power for the various components of the wireless device 300. The power management system 320 can further include one or more processors or controllers that can control the transmission of signals, for example. In one embodiment, the baseband sub-system 330 is connected to a user interface 340 to facilitate various input and output of voice and/or data provided to and received from the user. The baseband sub-system 330 can also be connected to memory 350 that is configured to store data and/or instructions to facilitate the operation of the wireless device, and/or to provide storage of information for the user. Any of the embodiments described above can be implemented in association with mobile devices such as cellular handsets. The principles and advantages of the embodiments can be used for any systems or apparatus, such as any uplink wireless communication device, that could benefit from any of the embodiments described herein. The teachings herein are applicable to a variety of systems. Although this disclosure includes some example embodiments, the teachings described herein can be applied to a variety of structures. Any of the principles and advantages discussed herein can be implemented in association with RF circuits configured to process signals in a range from about 30 kHz to 5 GHz, such as in a range from about 600 MHz to 2.7 GHZ.

Aspects of this disclosure can be implemented in various electronic devices. Examples of the electronic devices can include, but are not limited to, consumer electronic products, parts of the consumer electronic products such as packaged radio frequency modules, uplink wireless communication devices, wireless communication infrastructure, electronic test equipment, etc. Examples of the electronic devices can include, but are not limited to, a mobile phone such as a smart phone, a wearable computing device such as a smart watch or an ear piece, a telephone, a television, a computer monitor, a computer, a modem, a hand-held computer, a laptop computer, a tablet computer, a microwave, a refrigerator, a vehicular electronics system such as an automotive electronics system, a stereo system, a digital music player, a radio, a camera such as a digital camera, a portable memory chip, a washer, a dryer, a washer/dryer, a copier, a facsimile machine, a scanner, a multi-functional peripheral device, a wrist watch, a clock, etc. Further, the electronic devices can include unfinished products.

Unless the context clearly requires otherwise, throughout the description and the claims, the words “comprise,” “comprising,” “include,” “including” and the like are to be construed in an inclusive sense, as opposed to an exclusive or exhaustive sense; that is to say, in the sense of “including, but not limited to”. The word “coupled,” as generally used herein, refers to two or more elements that may be either directly connected, or connected by way of one or more intermediate elements. Likewise, the word “connected,” as generally used herein, refers to two or more elements that may be either directly connected, or connected by way of one or more intermediate elements. Additionally, the words “herein,” “above,” “below,” and words of similar import, when used in this application, shall refer to this application as a whole and not to any particular portions of this application. Where the context permits, words in the above Detailed Description using the singular or plural number may also include the plural or singular number respectively. The word “or” in reference to a list of two or more items, that word covers all of the following interpretations of the word: any of the items in the list, all of the items in the list, and any combination of the items in the list.

Moreover, conditional language used herein, such as, among others, “can,” “could,” “might,” “may,” “e.g.,” “for example,” “such as” and the like, unless specifically stated otherwise, or otherwise understood within the context as used, is generally intended to convey that certain embodiments include, while other embodiments do not include, certain features, elements and/or states. Thus, such conditional language is not generally intended to imply that features, elements and/or states are in any way required for one or more embodiments or that one or more embodiments necessarily include logic for deciding, with or without author input or prompting, whether these features, elements and/or states are included or are to be performed in any particular embodiment.

While certain embodiments have been described, these embodiments have been presented by way of example only, and are not intended to limit the scope of the disclosure. Indeed, the novel apparatus, methods, and systems described herein may be embodied in a variety of other forms; furthermore, various omissions, substitutions and changes in the form of the methods and systems described herein may be made without departing from the spirit of the disclosure. For example, while blocks are presented in a given arrangement, alternative embodiments may perform similar functionalities with different components and/or circuit topologies, and some blocks may be deleted, moved, added, subdivided, combined, and/or modified. Each of these blocks may be implemented in a variety of different ways. Any suitable combination of the elements and acts of the various embodiments described above can be combined to provide further embodiments. The accompanying claims and their equivalents are intended to cover such forms or modifications as would fall within the scope and spirit of the disclosure.

1. A die including a plurality of surface acoustic wave resonators comprising:
a substrate including at least one piezoelectric material layer;
at least one single-mode surface acoustic wave (SAW) resonator disposed on the substrate and including at least one electrode that is at least partially buried within the at least one piezoelectric material layer and that forms one of an interdigital transducer (IDT) electrode or a reflector electrode of the single-mode SAW resonator; and
at least one dual mode surface acoustic wave (DMS) resonator disposed on the substrate and including interdigital transducer electrodes and reflector electrodes, none of the interdigital transducer electrodes and reflector electrodes of the at least one DMS resonator being at least partially buried within the at least one piezoelectric material layer.

2. The die of claim 1 wherein the substrate is a multilayer piezoelectric substrate.

3. The die of claim 2 wherein the electrode of the at least one single-mode SAW resonator is one of a multi-layer electrode including a layer of one of Mo, Pt, Ir, or W, or a single layer electrode including one of Mo, Pt, Ir, or W.

4. The die of claim 1 wherein the substrate includes a plurality of piezoelectric material layers.

5. The die of claim 4 wherein the at least one electrode of the at least one single-mode SAW resonator extends into each of the plurality of piezoelectric material layers.

6. The die of claim 4 wherein the at least one electrode of the at least one single-mode SAW resonator is a multi-layer electrode including a lower electrode layer extending into at least one of the plurality of piezoelectric material layers and an upper electrode layer disposed above each of the plurality of piezoelectric material layers.

7. The die of claim 6 wherein the lower electrode layer extends into each of the plurality of piezoelectric material layers.

8. The die of claim 1 wherein the electrode of the at least one single-mode SAW resonator is an IDT electrode including bus bar electrodes and IDT electrode fingers each at least partially buried within the at least one piezoelectric material layer.

9. The die of claim 1 wherein the electrode of the at least one single-mode SAW resonator is an IDT electrode including IDT electrode fingers each at least partially buried within the at least one piezoelectric material layer and bus bar electrodes that are not at least partially buried within the substrate.

10. The die of claim 1 wherein the at least one electrode of the at least one single-mode SAW resonator is a reflector electrode.

11. The die of claim 10 wherein the at least one electrode of the at least one single-mode SAW resonator further includes an IDT electrode that is not at least partially buried within the substrate.

12. The die of claim 1 wherein the at least one single-mode SAW resonator includes a plurality of single-mode SAW resonators electrically connected and forming at least a portion of a radio frequency filter.

13. The die of claim 12 wherein the DMS resonator is electrically connected to the plurality of single-mode SAW resonators and is included in the radio frequency filter.

14. The die of claim 13 wherein the plurality of single-mode SAW resonators and the DMS resonator form a radio frequency duplexer.

15. The die of claim 14 wherein each of the resonators in a transmit side filter of the duplexer are at least partially buried within the at least one piezoelectric material layer and no resonators in a receive side filter of the duplexer are at least partially buried in the substrate.

16. The die of claim 14 wherein each of the resonators in a transmit side filter of the duplexer are at least partially buried within the at least one piezoelectric material layer, a first subset of resonators in a receive side filter of the duplexer closer to an antenna port of the duplexer than a second subset of resonators in the receive side filter of the duplexer is at least partially buried within the at least one piezoelectric material layer, and no resonators in the second subset of resonators are at least partially buried in the substrate.

17. The die of claim 14 wherein a first subset of the resonators in a transmit side filter of the duplexer further from an antenna port of the duplexer than a second subset of the resonators in the transmit side filter of the duplexer are at least partially buried within the at least one piezoelectric material layer, and no resonators in the second subset or in a receive side filter of the duplexer are at least partially buried in the substrate.

18. A radio frequency device module including the duplexer of claim 14.

19. A radio frequency device including the radio frequency device module of claim 18.

20. A method of forming a die including a plurality of surface acoustic wave resonators, the method comprising:
depositing a first layer of photoresist on an upper surface of a piezoelectric material layer of a substrate;
developing the first layer of photoresist to form a first plurality apertures in the first layer of photoresist through which portions of the piezoelectric material layer are exposed;
etching recesses within the exposed portions of the piezoelectric material layer;
removing remaining portions of the first layer of photoresist from the upper surface of the piezoelectric material layer;
depositing a first metal layer within the recesses, regions of the upper surface of the piezoelectric material layer other than the recesses being free of the first metal layer;
depositing a second metal layer on the upper surface of the piezoelectric material layer and over the first metal layer within the recesses;
depositing a second layer of photoresist on an upper surface of the second metal layer;
developing the second layer of photoresist to form a second plurality apertures in the second layer of photoresist through which portions of the second metal layer are exposed, portions of the second layer of photoresist remaining disposed over the recesses; and
etching the second metal layer through the second plurality of apertures to define first regions of the second metal layer disposed on the upper surface of the piezoelectric material layer both above and in contact with the first metal layer and second regions of the second metal layer disposed on the upper surface of the piezoelectric material layer and laterally displaced from the recesses.
